(19) United States
(12) Patent Application Publication
(10) Pub. No.: US 2026/0188230 A1
(43) Pub. Date: Jul. 2, 2026

(54) DISPLAY APPARATUS

(71) Applicant: LG Display Co., Ltd., Seoul (KR)

(72) Inventor: Minwoo Park, Paju-si (KR)

(73) Assignee: LG Display Co., Ltd., Seoul (KR)

(21) Appl. No.: 19/429,971

(22) Filed: Dec. 22, 2025

(30) Foreign Application Priority Data
Dec. 31, 2024 (KR) 10-2024-0201890

(51) Int. Cl. G09G 3/3233; G09G 3/3266

(52) U.S. Cl. CPC G09G 3/3233; G09G 3/3266; G09G 2300/0819; G09G 2300/0842; G09G 2300/0861; G09G 2310/0281; G09G 2310/0286; G09G 2310/08; G09G 2320/0238; G09G 2330/021; G09G 2340/0435

(57) ABSTRACT

An embodiment of the present disclosure comprises the pixel circuit including a drive transistor, a first thin film transistor in response to a first scan signal, a second thin film transistor in response to a second scan signal, a third thin film transistor arranged to connect the high-potential power line to the first node of the drive transistor in response to an (N+1) scan signal of the (N+1)th row line, and a fourth thin film transistor and a fifth thin film transistor that respond to a light emission control signal.

### CROSS-REFERENCE TO RELATED APPLICATION

This application claims the benefit of priority of the Republic of Korea Patent Application No. 10-2024-0201890, filed on Dec. 31, 2024, which is hereby incorporated by reference in its entirety.

### BACKGROUND

### Field of Technology

The present disclosure relates to a display apparatus capable of reducing the configuration of a gate driving circuit.

### Discussion of the Related Art

The electroluminescent display apparatuses have the advantages of high brightness, low operating voltage, ultra-thinness, and freedom of shape implementation by utilizing self-luminous elements.

In an electroluminescent display apparatus, each pixel constituting the display panel may be independently driven by a pixel circuit.

In an electroluminescent display apparatus, a gate driving circuit that controls thin film transistors of a pixel circuit may be disposed in a bezel area of a display panel. Since the gate driving circuit includes a plurality of scan driving circuits that apply a plurality of scan signals to the pixel circuit and a plurality of light emission control driving circuits that apply a plurality of emission control signals, the bezel area may be enlarged.

The electroluminescent display apparatuses may be driven at a low frequency (1 Hz) to reduce power consumption. However, when driven at low frequency, the plurality of light emission control driving circuits continuously generate multiple light emission control signals even during the anode reset period, limiting reduction in power consumption.

### SUMMARY

Accordingly, the present disclosure is directed to providing a display apparatus that substantially obviates one or more problems due to limitations and disadvantages of the related art.

In one aspect, the present disclosure provides a display apparatus capable of reducing a bezel area and achieving low power consumption by reducing the configuration of a gate driving circuit.

In another aspect, the present disclosure provides a display apparatus capable of improving picture quality by securing an initialization voltage variable margin.

Additional advantages and features of the disclosure will be set forth in part in the description which follows and in part will become apparent to those having ordinary skill in the art upon examination of the following or may be learned from practice of the disclosure. The technical benefits and other advantages of the disclosure may be realized and attained by the structure particularly pointed out in the written description and claims hereof as well as the appended drawings.

To achieve these and other advantages and in accordance with the purpose of the present disclosure, as embodied and broadly described herein, a display apparatus according to one or more embodiments of the present disclosure includes a plurality of subpixels disposed in a display area of a display panel, each of the plurality of subpixels including a light emitting element and a pixel circuit configured to independently drive the light emitting element, wherein the pixel circuit may include a driving transistor arranged to drive the light emitting element, a first thin film transistor arranged to connect a first node and a second node of the driving transistor in response to a first scan signal, a second thin film transistor arranged to connect a third node of the driving transistor and a data line in response to a second scan signal, a third thin film transistor arranged to connect a high-potential power line and the first node of the driving transistor in response to an (N+1) scan signal of an (N+1)th row line, N being a positive integer, a fourth thin film transistor arranged to connect the third node of the driving transistor and the light emitting element in response to a light emission control signal, a fifth thin film transistor arranged to connect an initialization voltage line and a fourth node of the light emitting element in response to the light emission control signal, and a storage capacitor connected between the second node of the driving transistor and the fourth node of the light emitting element.

The display apparatus according to one embodiment of the present disclosure may include a display panel, and a plurality of subpixels disposed in the display area of a display panel, wherein each of the plurality of subpixels includes a light emitting element and a pixel circuit configured to independently drive the light emitting element, wherein the pixel circuit includes: a driving transistor driving the light emitting element; a first thin film transistor arranged to connect a first node and a second node of the driving transistor in response to a first scan signal; and a third thin film transistor arranged to connect a high-potential power line and the first node of the driving transistor in response to a (N+1) scan signal of an N+1th row line, wherein N is a positive integer, wherein Nth row line and the N+1th row line share the (N+1) scan signal.

The display apparatus according to one or more embodiments of the present disclosure may further include a gate driving circuit disposed in a bezel area of the display panel, and the gate driving circuit may include a first scan driving circuit that is configured to supply the first scan signal and the (N+1) scan signal, a second scan driving circuit that is configured to supply a second scan signal, and a light emission control driving circuit that is configured to supply a light emission control signal.

It is to be understood that both the foregoing general description and the following detailed description of the present disclosure are by way of example and explanatory and are intended to provide further explanation of the disclosure.

### BRIEF DESCRIPTION OF THE DRAWINGS

The accompanying drawings, which are included to provide a further understanding of the present disclosure and are incorporated in and constitute a part of this application, illustrate example embodiments of the present disclosure and together with the description serve to explain various principles of the disclosure.

FIG. 1 is a schematic diagram illustrating the configuration of a display apparatus according to an example embodiment of the present disclosure.

FIG. 2 is an equivalent circuit diagram illustrating the configuration of a pixel circuit according to an example embodiment of the present disclosure.

FIG. 3 is a drawing illustrating a portion of a display panel including a gate driving circuit according to an example embodiment of the present disclosure.

FIG. 4 is a diagram illustrating an example driving waveform of the gate driving circuit illustrated in FIG. 3.

FIG. 5 is a diagram illustrating an example driving waveform of the pixel circuit illustrated in FIG. 2 and a potential state of each node.

FIG. 6 is a graph showing the effect of increasing the initialization voltage margin according to an example embodiment of the present disclosure.

FIG. 7 is a diagram illustrating a driving frequency according to an example embodiment of the present disclosure.

FIGS. 8A and 8B are diagrams each illustrating a driving waveform of a gate driving circuit according to an example embodiment of the present disclosure.

FIG. 9 is a graph showing the power consumption reduction effect of a gate driving circuit according to an example embodiment of the present disclosure.

### DETAILED DESCRIPTION

Advantages and features of the present disclosure, and implementation methods thereof will be clarified through the following example embodiments, described with reference to the accompanying drawings. The present disclosure may, however, be embodied in different forms and should not be construed as being limited to the embodiments set forth herein. Rather, these example embodiments are provided so that this disclosure will be more thorough and complete, and will more fully convey various aspects and features of the present disclosure to those skilled in the art without limiting the protected scope of the present disclosure.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, where the detailed description of the relevant known function or configuration may unnecessarily obscure the important point of the present disclosure, such detailed description may be omitted.

Where terms like “comprise,” “have,” and “include” are used in the description, another part may also be present unless a more specific term like “only” is used. The terms in a singular form may include plural forms, and vice versa, unless noted to the contrary.

In construing an element, the element is to be construed as including an error region although there is no explicit description thereof.

In describing a positional relationship, for example, where the positional order or relationship is described as “on,” “above,” “below,” “beneath,” and “next,” the case of no contact therebetween may be included, unless a more specific term like “just” or “direct” is used.

If a first element is described as positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, where the temporal order is described as “after,” “subsequent,” “next,” and “before,” a case which is not continuous may be included, unless a more specific term like “just” or “direct” is used.

It will be understood that, although the terms “first,” “second,” etc., may be used herein to describe various elements, these elements should not be limited by these terms. These terms are only used to refer to one element separately from another. For example, a first element could be termed a second element, and, similarly, a second element could be termed a first element.

It should be understood that the term “at least one” includes all combinations related with any one item. For example, “at least one among a first element, a second element, and a third element” may include all combinations of two or more elements selected from the first, second, and third elements as well as each of the first, second, and third elements individually.

Features of various embodiments of the present disclosure may be partially or overall coupled to or combined with each other, and may be variously inter-operated with each other and driven technically. The embodiments of the present disclosure may be carried out independently from each other, or may be carried out together in a co-dependent relationship.

Hereinafter, various aspects of the present disclosure will be described with reference to the accompanying drawings. Since a scale of each of elements shown in the accompanying drawings may be different from an actual scale for convenience of description, the present disclosure is not limited to the shown scale. Further, all the components of each display apparatus, display device, and display panel according to all aspects of the present disclosure are operatively coupled and configured.

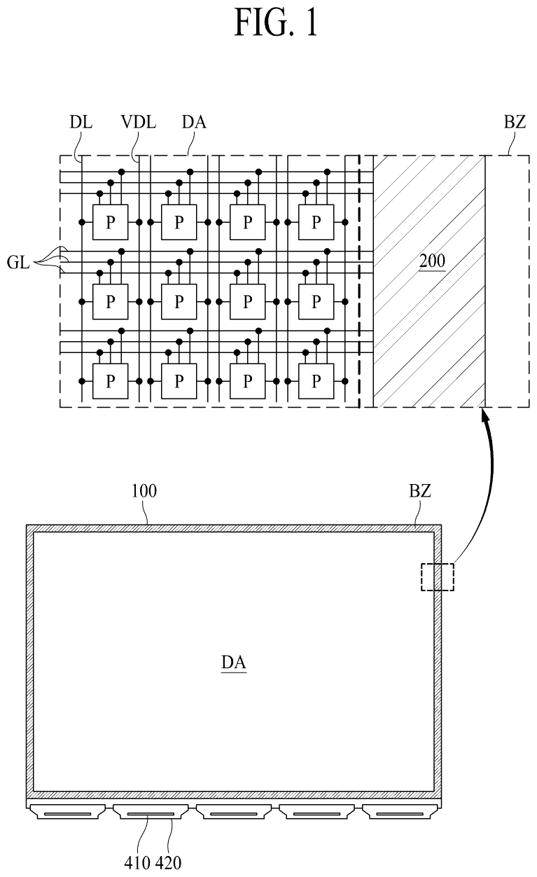

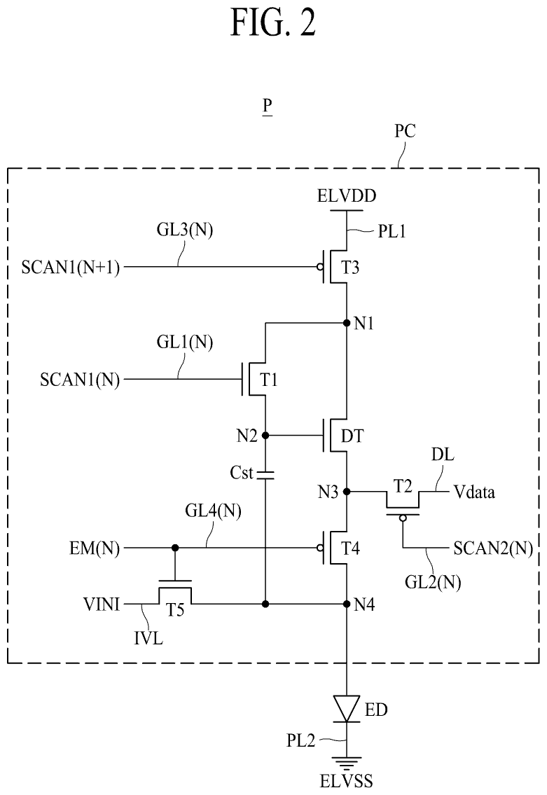

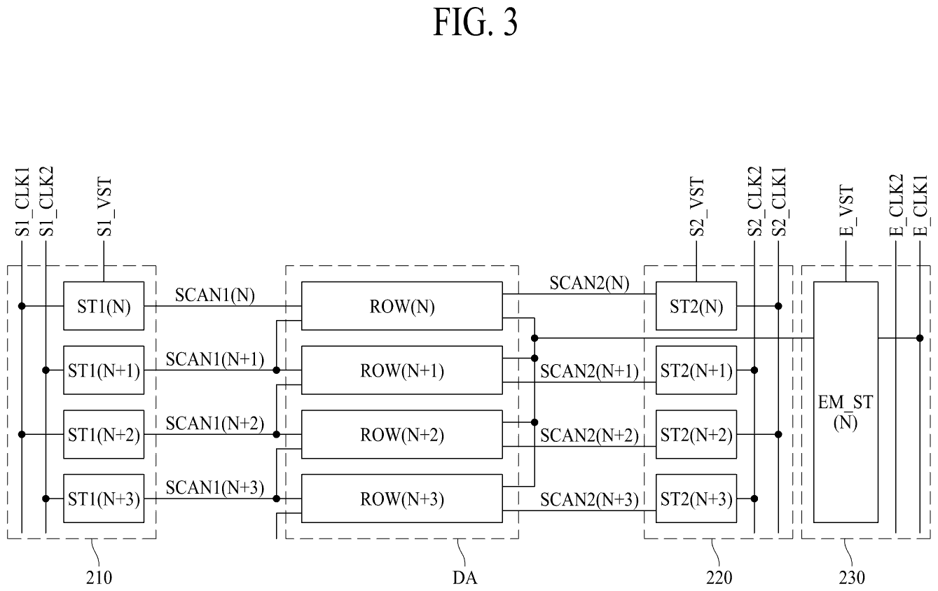

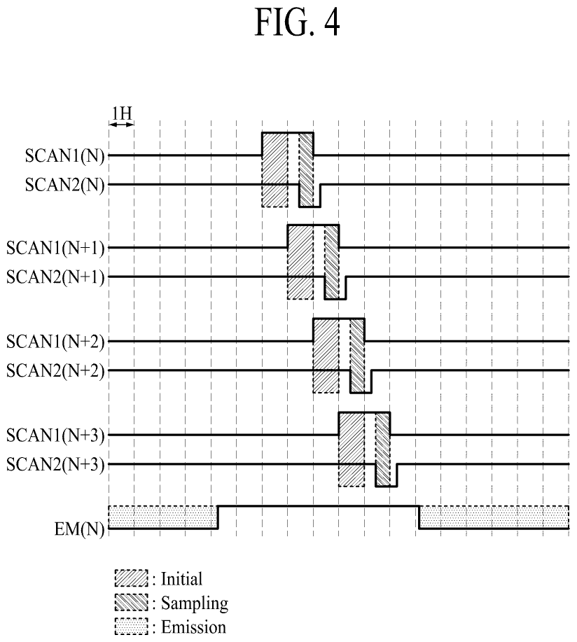

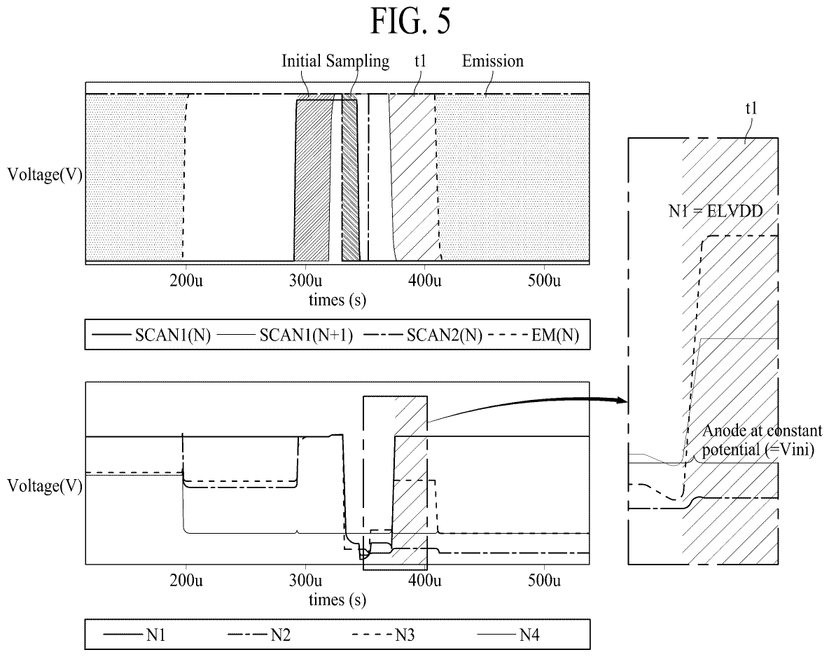

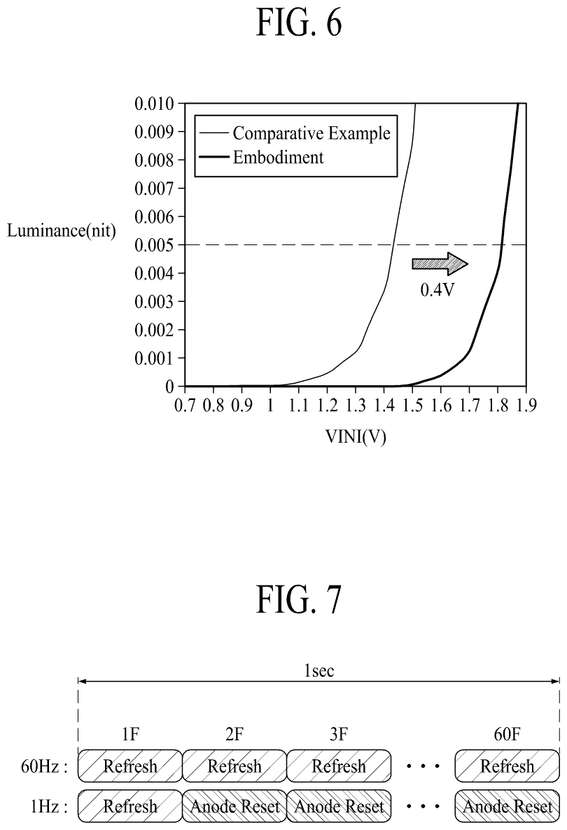

FIG. 1 is a schematic diagram illustrating a configuration of a display apparatus according to an example embodiment of the present disclosure, FIG. 2 is an equivalent circuit diagram illustrating a configuration of a pixel circuit according to an example embodiment of the present disclosure, FIG. 3 is a diagram illustrating a portion of a display panel including a gate driving circuit according to an example embodiment of the present disclosure, and FIG. 4 is a diagram illustrating an example driving waveform of the gate driving circuit illustrated in FIG. 3. FIG. 5 is a diagram illustrating an example driving waveform of the pixel circuit illustrated in FIG. 2 and a potential state of each node, and FIG. 6 is a graph showing an effect of increasing an initialization voltage margin according to an example embodiment of the present disclosure.

The display apparatus according to an example embodiment may be an electroluminescent display apparatus. The electroluminescent display apparatus may be any one of an organic light emitting diode (OLED) display apparatus, a quantum-dot light emitting diode (QD) display apparatus, and an inorganic light emitting diode (ILD) display apparatus.

As shown in FIG. 1, a display apparatus according to an example embodiment may include a display panel 100, a gate driving circuit 200 built into the display panel 100, and a data driving circuit 410 connected to the display panel 100. The gate driving circuit 200 and the data driving circuit 410 may be expressed as a display driving circuit.

The display panel 100 may be a rigid display panel or a flexible display panel capable of changing shape, such as a foldable, bendable, rollable, or stretchable display panel.

The display panel 100 may include a display area DA and a bezel area BZ corresponding to a non-display area disposed at the outer edge surrounding the display area DA.

The display panel 100 may display an image through a pixel array in which subpixels P are disposed in a matrix form in the display area DA. The pixel array of the display area DA may include a plurality of row lines composed of a plurality of subpixels P disposed in a first direction (horizontal direction) and a plurality of column lines composed of a plurality of subpixels P disposed in a second direction (vertical direction).

The unit pixel may include a plurality of subpixels P having different emission colors. The unit pixel may include first to third subpixels that emit different colors. The first to third subpixels may be red, green, and blue subpixels that emit red light, green light, and blue light, respectively, but are not limited thereto. The unit pixel may additionally include a fourth subpixel that emits white light.

Each subpixel P may include a light emitting element and a pixel circuit composed of a plurality of thin film transistors that independently drive the light emitting element. The display panel 100 may include a plurality of data lines DL, a plurality of gate lines GL, a plurality of power lines VDL, and other signal lines connected to a plurality of subpixels P.

The display panel 100 according to an example embodiment may further include a touch sensor array disposed in the display area DA to sense a user's touch.

The gate driving circuit 200 may be disposed in at least one bezel area BZ of the display panel 100. For example, the gate driving circuit 200 may be disposed in first and second bezel areas BZ facing each other with the display area DA interposed therebetween. The gate driving circuit 200 may be built into the display panel 100 in the form of a gate in panel (GIP) formed together with thin film transistors of the display area DA.

The gate driving circuit 200 may include a plurality of driving circuits that drive a plurality of gate lines GL. For example, the gate driving circuit 200 may include a first scan driving circuit that supplies a first scan signal to each of the gate lines of a first group among the plurality of gate lines GL, a second scan driving circuit that supplies a second scan signal to each of the gate lines of a second group, and a light emission control driving circuit that supplies a light emission control signal to each of the gate lines of a third group. The number of gate lines GL connected to the subpixels P of each row line, the number of scan driving circuits, and the number of light emission control driving circuits may vary depending on the detailed configuration of the pixel circuit constituting each subpixel P.

The data driving circuit 410 may convert digital image data supplied from a timing controller into an analog data voltage and supply the data voltage to each of the plurality of data lines DL of the display panel 100. The data driving circuit 410 includes one or a plurality of ICs (Integrated Circuits), and may be mounted on each circuit film 420 and electrically connected to a pad area disposed in a bezel area BZ of the display panel 100 through an anisotropic conductive film (ACF). The circuit film 420 may be any one of a COF (Chip On Film), an FPC (Flexible Printed Circuit), and an FFC (Flexible Flat Cable).

The thin film transistors included in the driving circuit including the gate driving circuit 200 disposed in the display area DA and the bezel area BZ of the display panel 100 may include any one of a polysilicon semiconductor, an amorphous silicon semiconductor, and an oxide semiconductor. In an example embodiment, the thin film transistors of the display panel 100 may include at least any one of a low temperature polysilicon (LTPS) transistor and an oxide transistor using a metal-oxide semiconductor.

As shown in FIG. 2, the subpixel P according to an example embodiment may include a light emitting element ED and a pixel circuit PC that independently drives the light emitting element ED. The pixel circuit PC may include a driving thin film transistor DT, a plurality of thin film transistors T1 to T5, and a storage capacitor Cst.

Each of the thin film transistors DT and T1 to T5 of the pixel circuit PC may be a thin film transistor using any one of a polysilicon semiconductor, an amorphous silicon semiconductor, and an oxide semiconductor. In an example embodiment, the thin film transistors DT and T1 to T5 of the pixel circuit PC may be configured as P-type polysilicon transistors. In an example embodiment, the thin film transistors DT and T1 to T5 of the pixel circuit PC may be configured as N-type oxide transistors. In an example embodiment, the thin film transistors DT and T1 to T5 of the pixel circuit PC may be configured by mixing P-type polysilicon transistors and N-type oxide transistors.

In the pixel circuit PC according to an example embodiment, the second, third, and fourth thin film transistors T2, T3, and T4 may be configured as P-type LTPS (Low Temperature Polycrystalline Silicon) transistors having high mobility. In the pixel circuit PC according to an example embodiment, the driving transistor DT and the first and fifth thin film transistors T1 and T5 may be configured as N-type oxide transistors having a smaller off-state current (leakage current) than the LTPS transistors.

A subpixel P disposed in the Nth, wherein N is a positive integer, row line may be connected to the first to fourth gate lines GL1(N) to GL4(N) disposed in the Nth row line, and may be connected to a data line DL, and first and second power lines PL1 and PL2.

Each subpixel P may be driven to include an initialization period, a sampling period, and a light emission period for each frame.

The first thin film transistor T1 as a sampling transistor may be controlled by a first gate line GL1(N) and may connect a second node N2 to which a gate electrode of the driving transistor DT is connected and a first node N1 to which a drain electrode (a second electrode) of the driving transistor DT is connected. The first thin film transistor T1 may connect the gate electrode and the drain electrode of the driving transistor DT in a diode structure during the initialization period and the sampling period in response to a first scan signal SCAN1(N) of the first gate line GL1(N). The first thin film transistor T1, which is composed of an N-type oxide transistor, may be turned on by a gate high voltage (a gate-on voltage) of the first scan signal SCAN1(N) and may be turned off by a gate low voltage (a gate-off voltage).

The second thin film transistor T2 as a switching transistor may be controlled by a second gate line GL2(N) and may connect the data line DL and a third node N3 connected to a source electrode (first electrode) of the driving transistor DT. The second thin film transistor T2 may apply a data voltage Vdata supplied through the data line DL to the driving transistor DT during the sampling period in response to a second scan signal SCAN2(N) of the second gate line GL2(N). The second thin film transistor T2, which is composed of a P-type LTPS transistor, may be turned on by a gate low voltage (a gate-on voltage) of the second scan signal SCAN2(N) and may be turned off by a gate high voltage (a gate-off voltage).

The third thin film transistor T3 as an operation control transistor may be controlled by a third gate line GL3(N) and may connect the first power line PL1 supplying a high-potential power supply voltage ELVDD and the first node N1 of the driving transistor DT. The third thin film transistor T3 may apply the high-potential power supply voltage ELVDD supplied through the first power line PL1 to the driving transistor DT during the initialization period and the light emission period in response to a third scan signal SCAN1(N+1) supplied through the third gate line GL3(N). The third thin film transistor T3, which is composed of a P-type LTPS transistor, may be turned on by a gate low voltage (a gate-on voltage) of the third scan signal SCAN1(N+1) and may be turned off by a gate high voltage (a gate-off voltage). The third thin film transistor T3 composed of a P-type LTPS transistor may share the (N+1) scan signal SCAN1(N+1) supplied to the first thin film transistor T1 of the pixel circuit PC of the (N+1)th row line composed of an N-type oxide transistor, and use it as a third scan signal SCAN1(N+1).

Accordingly, the display apparatus according to an example embodiment in which the third thin film transistor T3 is controlled by the third scan signal, i.e., the (N+1) scan signal SCAN1(N+1) of the (N+1)-th row line, may reduce the number of light emission control circuits compared to the display apparatus according to the comparative example in which the third thin film transistor T3 is controlled by a different light emission control signal from the light emission control signal EM(N) supplied the fourth thin film transistor T4.

The fourth thin film transistor T4 as a light emitting control transistor is controlled by the fourth gate line GL4(N) and may connect the third node N3 of the driving transistor DT and a fourth node N4 connected to an anode electrode of the light emitting element ED. The fourth thin film transistor T4 may connect the driving transistor DT and the anode electrode of the light emitting element ED during the light emitting period in response to the light emission control signal EM(N) of the fourth gate line GL4(N). The fourth thin film transistor T4, which is composed of a P-type LTPS transistor, may be turned on by a gate low voltage (a gate-on voltage) of the light emission control signal EM(N) and may be turned off by a gate high voltage (a gate-off voltage).

The fifth thin film transistor T5 as an initialization transistor is controlled by the fourth gate line GL4(N) and may connect an initialization voltage line IVL to which an initialization voltage VINI is supplied and the fourth node N4 connected to the anode electrode of the light emitting element ED. The fifth thin film transistor T5 may apply the initialization voltage VINI to the anode electrode of the light emitting element ED during the initialization period and the sampling period excluding the light emitting period, in response to the light emission control signal EM(N) of the fourth gate line GL4(N). The initialization voltage VINI may be expressed as a reference voltage. The fifth thin film transistor T5 composed of an N-type oxide transistor may share the same light emission control signal EM(N) as the fourth thin film transistor T4 composed of a P-type LTPS transistor. In contrast to the fourth thin film transistor T4, the fifth thin film transistor T5 may be turned on by the gate high voltage (the gate on voltage) of the light emission control signal EM(N) and turned off by the gate low voltage (the gate off voltage).

In this way, by sharing the light emission control signal EM(N) between the fourth thin film transistor T4 and the fifth thin film transistor T5, the display apparatus according to an example embodiment may reduce the number of scan driving circuits.

A storage capacitor Cst is connected between the second node N2 and the fourth node N4, and may be charged with and hold the difference voltage (Vdata+Vth−VINI) between the data voltage (Vdata+Vth) compensated for the threshold voltage (Vth) of the driving transistor DT and the initialization voltage VINI as a target voltage during the sampling period, and may apply the held target voltage to the driving transistor DT during the light emission period.

The driving transistor DT may have the gate electrode connected to the second node N2, the source electrode (the first electrode) connected to the third node N3, and the drain electrode (the second electrode) connected to the first node N1. The driving transistor DT may control current according to the target voltage held in the storage capacitor Cst, supply current to the light emitting element ED through the fourth thin film transistor T4, and drive the light emitting element ED, and may adjust the brightness of the light emitting element ED according to the amount of current.

The light emitting element ED may include the anode electrode connected to the third node N3 of the driving transistor DT via the fourth thin film transistor T4, a cathode electrode connected to the second power line PL2 to which a low-potential power supply voltage ELVSS is applied, and a light emitting stack between the anode electrode and the cathode electrode. The light emitting element ED may generate light with a brightness proportional to the amount of current supplied from the driving transistor DT via the fourth thin film transistor T4.

As shown in FIGS. 1, 3, and 4, a gate driving circuit 200 disposed in a bezel area BZ of a display panel 100 according to an example embodiment may include a first scan driving circuit 210, a second scan driving circuit 220, and a light emission control driving circuit 230. The first and second scan driving circuits 210, 220 and the light emission control driving circuit 230 may be disposed in the first and second bezel areas BZ facing each other with the display area DA interposed therebetween.

For example, a first scan driving circuit 210 may be disposed in a first bezel area, a second scan driving circuit 220 may be disposed in a second bezel area, and a light emission control driving circuit 230 may be disposed in any one of the first and second bezel areas.

The first scan driving circuit 210 may include a plurality of first scan stage circuits ST1(N), ST1(N+1), ST1(N+2), and ST1(N+3) that receive a first scan start signal S1_VST and first scan clock signals S1_CLK1, S1_CLK2 and sequentially output a plurality of first scan signals SCAN1(N), SCAN1(N+1), SCAN1(N+2), and SCAN1(N+3). The plurality of first scan stage circuits ST1(N) to ST1(N+3) may output a plurality of first scan signals SCAN1(N) to SCAN1(N+3) to each of a plurality of row lines ROW(N), ROW(N+1), ROW(N+2), and ROW(N+3) of the display area DA. Each of the plurality of first scan stage circuits ST1(N) to ST1(N+3) may also apply the corresponding first scan signal SCAN1(N) to SCAN1(N+3) to a previous row line. The plurality of first scan signals SCAN1(N) to SCAN1(N+3) may have a form in which the gate high voltage of 2 horizontal periods (2H) in each frame is phase-shifted by 1 horizontal period 1H, and may have the gate low voltage for the remaining period of each frame.

The second scan driving circuit 220 may include a plurality of second scan stage circuits ST2(N) to ST2(N+3) that receive a second scan start signal S2_VST and second scan clock signals S2_CLK1, S2_CLK2 and sequentially output a plurality of second scan signals SCAN2(N) to SCAN2(N+3). The plurality of second scan stage circuits ST2(N) to ST2(N+3) may output a plurality of second scan signals SCAN2(N) to SCAN2(N+3) to each of a plurality of row lines ROW(N) to ROW(N+3). The plurality of second scan signals SCAN2(N) to SCAN2(N+3) may have a form in which the gate low voltage of 1 horizontal period (1H) in each frame is phase-shifted by 1 horizontal period (1H), and may have the gate high voltage for the remaining period of each frame.

The light emission control driving circuit 230 may include a plurality of light emission control stage circuits EM_ST(N) that receive an EM start signal E_VST and EM clock signals E_CLK1, E_CLK2 and output a plurality of light emission control signals EM(N), respectively. The plurality of light emission control stage circuits EM_ST(N) may output the light emission control signals EM(N) in units of a plurality of row lines ROW(N) to ROW(N+3) of the display area DA. For example, each light emission control stage circuit EM_ST(N) may output the light emission control signals EM(N) in common to four row lines ROW(N) to ROW(N+3). Accordingly, the light emission control driving circuit 230 may reduce the number of light emission control stage circuits EM_ST(N) to ¼ of the number of row lines ROW(N) to ROW(N+3). Each light emission control signal EM(N) may have the gate high voltage of 8 horizontal periods (8H) including the initialization period and sampling period of each of the four row lines ROW(N) to ROW(N+3) in each frame, and may have the gate low voltage for the remaining period of each frame corresponding to the light emission period of the four row lines ROW(N) to ROW(N+3).

As shown in FIGS. 2 to 5, the first gate line GL1(N) may receive a first scan signal SCAN1(N) from the first (N) scan stage circuit ST1(N) of the first scan driving circuit 210 and may apply the first scan signal SCAN1(N) to the subpixel P of the Nth row line ROW(N). The second gate line GL2(N) may receive a second scan signal SCAN2(N) from the second (N) scan stage circuit ST2(N) of the second scan driving circuit 220 and may apply the second scan signal SCAN2(N) to the subpixel P of the Nth row line ROW(N). The third gate line GL3(N) may share the (N+1) scan signal SCAN1(N+1) supplied from the first (N+1) scan stage circuit ST1(N+1) of the first scan driving circuit 210 to the (N+1)th row line ROW(N+1) and may apply the (N+1) scan signal to the subpixel P of the Nth row line ROW(N). The fourth gate line GL4(N) may receive the light emission control signal EM(N) from the emission control stage circuit EM_ST(N) of the light emission control driving circuit 230 and may apply the light emission control signal EM(N) to the subpixel P of the Nth row line ROW(N).

The first scan signal SCAN1(N) supplied to the Nth row line ROW(N) may have the gate high voltage for a 2H period including an initialization period and a sampling period of the Nth row line ROW(N). A second scan signal SCAN2(N) supplied to the Nth row line ROW(N) may have the gate low voltage for a 1H period including a sampling period of the Nth row line ROW(N). The (N+1) scan signal SCAN1(N+1) supplied to the Nth and (N+1)th row lines ROW(N), ROW(N+1) may have the gate high voltage of a 2H period including an initialization period and a sampling period of the (N+1)th row line ROW(N+1), and may overlap with the gate high voltage of the first scan signal SCAN1(N) including the sampling period of the Nth row line ROW(N) for a 1H period.

As shown in FIGS. 2 and 5, during the initialization period in the subpixel P of the Nth row line, the first thin film transistor T1 may be turned on in response to the gate high voltage of the first scan signal SCAN1(N), the third thin film transistor T3 may be turned on in response to the gate low voltage of the third scan signal SCAN1(N+1), the second thin film transistor T2 may be turned off in response to the gate high voltage of the second scan signal SCAN2(N). The fourth thin film transistor T4 may be turned off and the fifth thin film transistor T5 may be turned on in response to the gate high voltage of the light emission control signal EM(N). Accordingly, the high-potential power supply voltage ELVDD may be applied to the first, second, and third nodes N1, N2, and N3 of the driving transistor DT, and the initialization voltage VINI may be applied to the fourth node N4 of the light emitting element ED.

During the sampling period, the first thin film transistor T1 may be maintained in a turn-on state in response to the gate high voltage of the first scan signal SCAN1(N), the second thin film transistor T2 may be turned on in response to the gate low voltage of the second scan signal SCAN2(N), the third thin film transistor T3 may be turned off in response to the gate high voltage of the third scan signal SCAN1(N+1). The fourth thin film transistor T4 may be maintained in a turn-off state and the fifth thin film transistor T5 may be maintained in a turn-on state in response to the gate high voltage of the light emission control signal EM(N). Accordingly, the data voltage (Vdata+Vth) compensated for the threshold voltage Vth of the driving transistor DT may be applied to the second node N2 through the turned-on second thin film transistor T2 and the driving transistor DT connected in a diode structure, and the initialization voltage VINI may be applied to the fourth node N4.

During the light emission period, the first thin film transistor T1 may be turned off in response to the gate low voltage of the first scan signal SCAN1(N), the second thin film transistor T2 may be turned off in response to the gate high voltage of the second scan signal SCAN2(N), the third thin film transistor T3 may be turned on in response to the gate low voltage of the third scan signal SCAN1(N+1). The fourth thin film transistor T4 may be turned on and the fifth thin film transistor T5 may be turned off in response to the gate low voltage of the light emission control signal EM(N). Accordingly, the high-potential power supply voltage ELVDD may be applied to the first node N1 of the driving transistor DT, and the driving transistor DT may drive the light emitting element ED through the fourth thin film transistor T4 according to the target voltage held in the storage capacitor Cst.

As shown in FIG. 5, in the light emitting preparation period t1 before the light emitting period of the subpixel P of the Nth row line, the third thin film transistor T3 is turned on in response to the gate low voltage of the third scan signal SCAN1(N+1), and the fifth thin film transistor T5 may be maintained in a turn-on state in response to the gate high voltage of the light emission control signal EM(N). Accordingly, it may be seen that when the high-potential power supply voltage ELVDD is supplied to the first node N1 of the driving transistor DT through the third thin film transistor T3 in the light emitting preparation period t1 before the light emitting period, the fourth node N4 of the light emitting element ED may be maintained at the initialization voltage VINI through the fifth thin film transistor T5.

Accordingly, the display apparatus according to an example embodiment may prevent or suppress black luminance from increasing by continuously maintaining the initialization voltage VINI without increasing the potential of the fourth node N4 of the light emitting element ED along with the potential of the first node N1 when a high-potential power supply voltage ELVDD is applied to the first node N1 of the driving transistor DT at the start timing of the light emitting period or in the light emitting preparation period before the light emitting period.

Accordingly, as shown in FIG. 6, it may be seen that the display apparatus according to an example embodiment may secure an additional variable margin of about 0.4 V of the initialization voltage VINI that may stably display black luminance without increasing black luminance when the data voltage of the black gradation is fixed by preventing or suppressing the potential rise of the fourth node N4 in the light emission preparation period.

Meanwhile, the comparative example in FIG. 6 may correspond to a display apparatus having a pixel circuit in which a third thin film transistor T3 is controlled by a light emission control signal EM(N) and a fourth thin film transistor T4 is controlled by another light emission control signal EM(N−2) (not shown). In the display apparatus according to this comparative example, when a high-potential power supply voltage ELVDD is applied to the first node N1 at the start timing of the light emission period, the potential of the fourth node N4 may rise, thereby increasing the black luminance, so that it may be seen that the variable margin of the initialization voltage VINI for displaying the black luminance is smaller than that of the display apparatus according to an example embodiment.

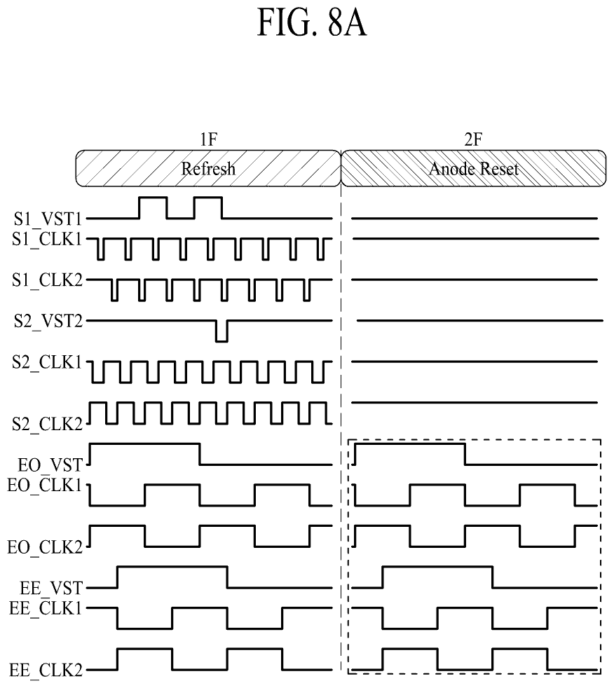

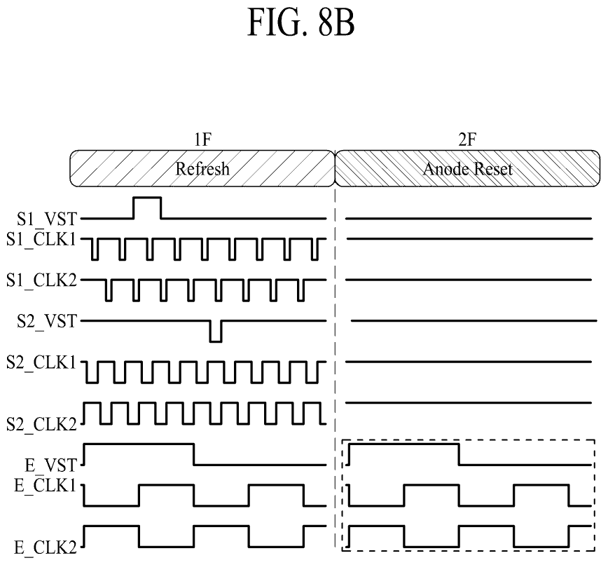

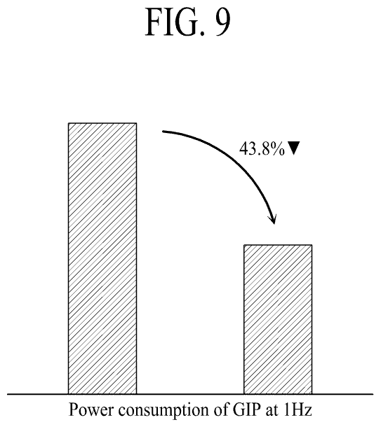

FIG. 7 is a diagram illustrating a driving frequency according to an example embodiment of the present disclosure, FIGS. 8A and 8B are diagrams each illustrating a driving waveform of a gate driving circuit according to an example embodiment of the present disclosure, and FIG. 9 is a graph showing a power consumption reduction effect of a gate driving circuit according to an example embodiment of the present disclosure.

As shown in FIG. 7, a display apparatus according to an example embodiment may be driven at a first driving frequency (60 Hz) or driven at a second driving frequency (1 Hz) to reduce power consumption.

The display apparatus driven at a first driving frequency (60 Hz) may be driven by including 60 refresh frames (1F to 60F) that charge a new data voltage Vdata to each of a plurality of subpixels P of the display panel 100 for each frame period.

The display apparatus driven by a second driving frequency (1 Hz) may be driven by a refresh frame for the first frame period 1F, and an anode reset frame for the remaining 59 frame periods (2F to 60F) that maintains a light emitting period and resets only the fourth node N4, which is the anode electrode of a light emitting element ED, to the initialization voltage VINI.

FIGS. 8A and 8B each illustrate a driving waveform of a gate driving circuit in a refresh frame period and an anode reset frame period of a display apparatus according to an example embodiment driven at a second driving frequency (1 Hz).

In an example embodiment of a display apparatus driven at a second driving frequency (1 Hz), during the refresh frame period 1F, the first scan driving circuit 210 may be driven according to a first set of scan control signals S1_VST1, S1_CLK1, S1_CLK2, the second scan driving circuit 220 may be driven according to a second set of scan control signals S2_VST2, S2_CLK1, S2_CLK2, and the light emission control driving circuit 230 may be driven according to a third set of control signals E_VST, E_CLK1, E_CLK2.

In a display apparatus according to an example embodiment driven at the second driving frequency (1 Hz), during an anode reset frame period 2F to 60F, the first set of scan control signals S1_VST1, S1_CLK1, S1_CLK2 and the second set of scan control signals S2_VST2, S2_CLK1, S2_CLK2 may be deactivated so that the first and second scan driving circuits 210, 220 may be turned off. The third set of control signals E_VST, E_CLK1, E_CLK2 may be supplied in a toggling form identical to the refresh frame period 1F so that the light emission control driving circuit 230 may output light emission control signals.

The display apparatus according to an example embodiment can reduce one set of light emission control driving circuits and reduce one set of control signals for light emission control driving circuits in each of a refresh frame period 1F and an anode reset frame period 2F to 60F, thereby reducing power consumption.

As shown in FIG. 9, it can be seen that the power consumption of the gate driving circuit (GIP) of the display apparatus according to an example embodiment driven at the second driving frequency (1 Hz) can be reduced by approximately 43.8% compared to the power consumption of the gate driving circuit (GIP) of the display apparatus according to the comparative example driven at the second driving frequency (1 Hz).

In this way, the display apparatus according to an example embodiment of the present disclosure can reduce the number of light emission control driving circuits compared to the comparative example in which the third thin film transistor of the pixel circuit is controlled by the light emission control signal by sharing the first scan signal of the next row line.

Therefore, the display apparatus according to an example embodiment of the present disclosure can reduce the bezel area occupied by the gate driving circuit by reducing the number of light emission control driving circuits, and can also achieve a low power consumption effect by reducing the power consumption of the gate driving circuit.

A display apparatus according to an example embodiment of the present disclosure can prevent or suppress potential of a fourth node connected to an anode electrode of a light emitting element from rising during a light emitting preparation period prior to a light emitting period, thereby suppressing a rise in black luminance, thereby securing an initialization voltage variable margin and improving image quality.

The above-described feature, structure, and effect of the present disclosure are included in at least one example embodiment of the present disclosure, but are not limited to only one embodiment. Furthermore, the feature, structure, and effect described in at least one example embodiment of the present disclosure may be implemented through combination or modification of other embodiments by those skilled in the art. Therefore, content associated with the combination and modification should be construed as being within the scope of the present disclosure.

It will be apparent to those skilled in the art that various substitutions, modifications, and variations are possible within the scope of the present disclosure without departing from the spirit and scope of the present disclosure. Therefore, the scope of the present disclosure includes those represented by the following claims, and all changes or modifications derived from the meaning, range, and equivalent concept of the claims should be interpreted as being included in the scope of the present disclosure.

The various example embodiments described above may be combined to provide further embodiments. Aspects of the embodiments may be modified to employ concepts of the various embodiments to provide yet further embodiments.

These and other changes may be made to the embodiments in light of the above-detailed description. In general, in the following claims, the terms used should not be construed to limit the claims to the specific example embodiments disclosed in the specification and the claims, but should be construed to include all possible embodiments along with the full scope of equivalents to which such claims are entitled. Accordingly, the claims are not limited by the disclosure.

What is claimed is:

1. A display apparatus, comprising:
a display panel; and
a plurality of subpixels disposed in a display area of the display panel, each of the plurality of subpixels including a light emitting element and a pixel circuit configured to independently drive the light emitting element,
wherein the pixel circuit includes:
a driving transistor arranged to drive the light emitting element;
a first thin film transistor arranged to connect a first node and a second node of the driving transistor in response to a first scan signal; and
a third thin film transistor arranged to connect a high-potential power line and the first node of the driving transistor in response to an (N+1) scan signal of an (N+1)th row line, N being a positive integer, and
wherein an Nth row line and the (N+1)th row line share the (N+1) scan signal.

2. The display apparatus of claim 1, wherein the pixel circuit further includes:
a second thin film transistor arranged to connect a third node of the driving transistor and a data line in response to a second scan signal;
a fourth thin film transistor arranged to connect the third node of the driving transistor and the light emitting element in response to a light emission control signal;
a fifth thin film transistor arranged to connect an initialization voltage line and a fourth node of the light emitting element in response to the light emission control signal; and
a storage capacitor connected between the second node of the driving transistor and the fourth node of the light emitting element.

3. The display apparatus of claim 2, wherein the driving transistor and the first to fifth thin film transistors include at least one of an oxide transistor and a polysilicon transistor.

4. The display apparatus of claim 1, wherein:
the first thin film transistor and the driving transistor are N-type oxide transistors; and
the third thin film transistor is a P-type polysilicon transistor.

5. The display apparatus of claim 2, wherein:
the fourth thin film transistor is a P-type polysilicon transistor; and
the fifth thin film transistor is an N-type oxide transistor.

6. The display apparatus of claim 2, wherein:
in each frame period, the pixel circuit includes an initialization period, a sampling period, a light emission preparation period, and a light emission period;
the first scan signal has a gate-high voltage during a first period including the initialization period and the sampling period, and has a gate-low voltage during remaining periods in each frame period other than the first period;
the second scan signal has the gate-low voltage during a second period including the sampling period, and partially overlaps the first period, and has the gate-high voltage during remaining periods in each frame period other than the second period; and
the light emission control signal has the gate-high voltage during a third period including initialization period, sampling period, and light emission preparation period of a plurality of row lines, and has the gate-low voltage during remaining periods in each frame period other than the third period.

7. The display apparatus of claim 6, wherein during the initialization period:
the first thin film transistor, the third thin film transistor, and the fifth thin film transistor are turned on, and the second and fourth thin film transistors are turned off;
a high-potential power supply voltage of the high-potential power line is applied to the first node, the second node, and the third node of the driving transistor; and
an initialization voltage of the initialization voltage line is applied to the fourth node of the light emitting element.

8. The display apparatus of claim 7, wherein during the sampling period:
the first and fifth thin film transistors remain turned on, the second thin film transistor is turned on, and the third and fourth thin film transistors are turned off;
a data voltage compensated for a threshold voltage of the driving transistor is applied to the second node of the driving transistor through the second thin film transistor and the driving transistor; and
the initialization voltage is maintained at the fourth node of the light emitting element.

9. The display apparatus of claim 8, wherein:
during the light emission preparation period, the third thin film transistor is turned on, the fifth thin film transistor remains turned on, and the first, second, and fourth thin film transistors are turned off; and
when the high-potential power supply voltage is applied to the first node of the driving transistor through the third thin film transistor, the initialization voltage is applied to the fourth node of the light emitting element.

10. The display apparatus of claim 9, wherein during the light emission period:
the third thin film transistor remains turned on, the fourth thin film transistor is turned on, and the first, second, and fifth thin film transistors are turned off; and
the driving transistor drives the light emitting element according to a voltage held in the storage capacitor.

11. The display apparatus of claim 2, further comprising a gate driving circuit disposed in a bezel area of the display panel, the gate driving circuit including:
a first scan driving circuit configured to supply the first scan signal and the (N+1) scan signal;
a second scan driving circuit configured to supply the second scan signal; and
a light emission control driving circuit configured to supply the light emission control signal.

12. The display apparatus of claim 11, wherein:
the first scan driving circuit is disposed in a first bezel area adjacent to one side of the display area;
the second scan driving circuit is disposed in a second bezel area adjacent to another side of the display area that is opposite the one side of the display area; and
the light emission control driving circuit is disposed in any one of the first and second bezel areas.

13. The display apparatus of claim 11, wherein during an anode reset frame period:
the first and second scan driving circuits are deactivated; and
only the light emission control driving circuit is activated to supply the light emission control signal.
